(19) United States
(12) Patent Application Publication
(10) Pub. No.: US 2012/0146646 A1
(43) Pub. Date: Jun. 14, 2012

(54) NANOPHOTONIC SYSTEM FOR OPTICAL DATA AND POWER TRANSMISSION IN MEDICAL IMAGING SYSTEMS

(75) Inventors: Sasikanth Manipatruni, Niskayuna, NY (US); Christopher Judson Hardy, Niskayuna, NY (US)

(73) Assignee: General Electric Company, Schenectady, NY (US)

(21) Appl. No.: 12/964,561

(22) Filed: Dec. 9, 2010

(51) Int. Cl. G01R 33/20; G05F 3/00; H04J 14/06

(52) U.S. Cl. 324/322; 398/65; 307/149

(57) ABSTRACT

The present disclosure is directed towards the transmission of data and/or power using nanophotonic elements. For example, in one embodiment, a medical imaging system is provided. The imaging system includes a multiplexed photonic data transfer system having an optical modulator configured to receive an electrical signal representative of a set of data and being operable to modulate a subset of photons defined by time, wavelength, or polarization contained within a beam of light so as to encode the photons with the set of data to produce encoded photons, an optical waveguide interfacing with at least a portion of the optical modulator and configured to transmit the beam of light so as to allow the photons to be modulated by the optical modulator, an optical resonator in communication with the optical waveguide and configured to remove the encoded photons from the beam of light, and a transducer optically connected to the optical resonator and configured to convert the encoded photons into the electrical signal representative of the set of data.

### BACKGROUND OF THE INVENTION

The subject matter disclosed herein relates to power, control and data conveyance within medical imaging systems, and more specifically, to the delivery of power, control and data via micro or nanophotonics.

Medical imaging systems often include components such as sources, detectors, and control circuitry to generate a diagnostically useful image. For example, in X-ray systems, X-ray radiation is emitted by an X-ray source in response to control signals during examination or imaging sequences. The radiation traverses a subject of interest, such as a human patient, and a portion of the attenuated radiation impacts a detector where the image data is collected.

In a positron emission tomography (PET) imaging system, a radionuclide is injected into a subject of interest. As the radionuclide decays, positrons are emitted that collide with electrons, resulting in an annihilation event that emits pairs of gamma particles. The pairs of gamma particles impact a detector array, which allows localization of the origin of the annihilation event. After a series of events are detected, localized concentrations of the radionuclide can be ascertained, leading to a diagnostic image.

In ultrasound imaging, a probe is typically employed that emits ultrasound waves into a portion of a subject of interest. Generation of sound wave pulses and detection of returning echoes, which results in an image, is typically accomplished via a plurality of transducers located in the probe.

In magnetic resonance imaging (MRI) systems, a highly uniform, static magnetic field is produced by a primary magnet to align the spins of gyromagnetic nuclei within a subject of interest (e.g., hydrogen in water/fats). The nuclear spins are perturbed by an RF transmit pulse, encoded based on their position using gradient coils, and allowed to equilibrate. During equilibration, RF fields are emitted by the spinning, precessing nuclei and are detected by a series of RF coils. The signals resulting from the detection of the RF fields are then processed to reconstruct a useful image.

In the imaging modalities mentioned above, it should be noted that the quality and resolution of a resulting image is largely a function of the number of detection elements (e.g., photodiodes, transducers, or coils) in their respective detector arrays. Advanced systems typically incorporate the greatest number of detection features possible. However, each detection feature typically requires a system channel that provides a means to electrically couple each detection feature to transmit and/or receive circuitry. Because there are typically a limited number of system channels available, the number of detection features in a given detector array is effectively limited. Such limitation in the number of detection features may effectively constrain scanning speed and the resolution attainable with a given type of detection array. Unfortunately, the channels mentioned above not only require extra electrical materials and power to amplify the signals produced by the detectors, but also greatly increase the weight and complexity of a given array. Accordingly, it is now recognized that there is a need for improved approaches towards data and/or power transmission in imaging and communication systems, especially those employing a large number of detection elements.

### BRIEF DESCRIPTION OF THE INVENTION

In one embodiment, a medical imaging system is provided. The imaging system includes a multiplexed photonic data transfer system having an optical modulator configured to receive an electrical signal representative of a set of data and being operable to modulate a subset of photons defined by time, wavelength, or polarization contained within a beam of light so as to encode the photons with the set of data to produce encoded photons, an optical waveguide interfacing with at least a portion of the optical modulator and configured to transmit the beam of light so as to allow the photons to be modulated by the optical modulator, an optical resonator in communication with the optical waveguide and configured to remove the encoded photons from the beam of light, and a transducer optically connected to the optical resonator and configured to convert the encoded photons into the electrical signal representative of the set of data.

In another embodiment, a medical imaging system having a photonic power delivery system is provided. The power delivery system includes a light source being operable to produce a beam of light, a waveguide coupled to the light source at a first end of the waveguide and configured to transmit the beam of light, and a transducer coupled to a second end of the waveguide and configured to convert the beam of light into an electrical power signal for powering a component of the medical imaging system.

In a further embodiment, an upgrade kit for a magnetic resonance imaging (MRI) system is provided. The kit includes a chip having a photonic data transmission system configured to interface with a plurality of radiofrequency (RF) coils and being operable to convert electrical data signals representative of magnetic resonance (MR) data generated at the RF coils into a multiplexed optical data signal representative of the MR data.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a block diagram illustrating an embodiment of a general imaging system that may incorporate nanophotonic power and/or data transmission, in accordance with an aspect of the present disclosure;

FIG. 2 is a block diagram illustrating an embodiment of an X-ray imaging system that may incorporate nanophotonic power and/or data transmission, in accordance with an aspect of the present disclosure;

FIG. 3 is a block diagram illustrating an embodiment of a positron emission tomography/single photon emission computed tomography (PET/SPECT) imaging system that may incorporate nanophotonic power and/or data transmission, in accordance with an aspect of the present disclosure;

FIG. 4 is a block diagram illustrating an embodiment of an ultrasound imaging system that may incorporate nanophotonic power and/or data transmission, in accordance with an aspect of the present disclosure;

FIG. 5 is a block diagram illustrating an embodiment of a magnetic resonance imaging system that may incorporate power and data transmission using nanophotonics, in accordance with an aspect of the present disclosure;

FIG. 6 is a diagrammatical illustration of an embodiment of image data transmission from the RF coil array of the MRI system of FIG. 5 using nanophotonics, in accordance with an aspect of the present disclosure;

FIG. 7 is a diagrammatical illustration an embodiment of image data transmission from and power delivery to the RF coil array of the MRI system of FIG. 5 using nanophotonics, in accordance with an aspect of the present disclosure;

FIG. 8 is a diagrammatical illustration an embodiment of image data transmission from and power and control signal transmission to the RF coil array of the MRI system of FIG. 5 using nanophotonics, in accordance with an aspect of the present disclosure;

FIG. 9 is a diagrammatical illustration an embodiment of a multi-channel multi-wavelength modulator array for conveying power, data, and/or control signals to and from the RF coil array of the MRI system of FIG. 5, in accordance with an aspect of the present disclosure;

FIG. 10 is a diagrammatical illustration of another embodiment of the array of FIG. 9, in accordance with an aspect of the present disclosure;

FIG. 11 is a diagrammatical illustration of another embodiment of the array of FIG. 9, in accordance with an aspect of the present disclosure;

FIG. 12 is a diagrammatical illustration of another embodiment of the array of FIG. 9, in accordance with an aspect of the present disclosure;

FIG. 13 is a diagrammatical illustration of another embodiment of the array of FIG. 9, in accordance with an aspect of the present disclosure;

FIG. 14 is a diagrammatical illustration of an embodiment of the integration of a nanophotonic modulator array with the RF coils of the MRI system of FIG. 5, in accordance with an aspect of the present disclosure.

FIG. 15 is a diagrammatical illustration of an embodiment of an interface between a resonant coil, an amplifier, and a thermally tunable optical modulator, in accordance with an aspect of the present disclosure; and

FIG. 16 is a diagrammatical illustration of an embodiment of an interface between a resonant coil, an amplifier, and an electrically tunable split-ring optical modulator, in accordance with an aspect of the present disclosure.

### DETAILED DESCRIPTION OF THE INVENTION

Certain considerations that may limit the number of channels available for a given imaging system can include the physical space of an imaging system, wherein there may not be enough room for an increased number of channels. Additionally, the weight of a system can be increased with increased cabling due to the presence of metal (e.g., conductive copper wire), shielding features (e.g., insulating covering on metal wiring), and other electrical conditioning features (e.g., baluns). Moreover, the area in which the imaging system is situated may require greater cooling as the electrical features generate heat.

In addition to such considerations, the imaging modality may also undesirably interact with the electrical power and communication signals. As one example, in an MRI system, there may be a number of electrical cables supplying power to and shuttling data between the RF coils and the MR control circuitry. The cabling typically includes copper or a similar conductive material, which can be affected by the strong radiofrequency fields generated by the magnetic resonance scanner. In some instances, the effect can be signal interference, degradation, and/or corruption, leading to irregular image data. Accordingly, in view of these shortcomings of traditional signal and power delivery via electrical channels, it is now recognized that there is a need for improved power delivery and data transmission in imaging systems.

The approaches described herein address these and other issues related to power and data transmission by providing nanophotonic devices and systems for realizing high-channel-count, high-bandwidth, and high-image-quality imaging systems. Using micron-sized devices with low energy and drive voltage requirements, an imaging system employing nanophotonic transmitters, receivers and wavelength division multiplexing (WDM) systems is described herein. As an example, the present approaches may result in a full optical interface with an imaging system detector array using nanophotonic interconnects and nanophotonic power delivery schemes. The photonic elements may include silicon-based features, which provide full compatibility with existing complimentary metal oxide semiconductor (CMOS) fabrication facilities and allow for mass manufacturing, low cost, and high-volume production. Moreover, the present embodiments enable a significant reduction in system cost and detector array weight, which can improve patient comfort, reduce overhead costs, increase patient safety, and result in better image quality. Technical effects of the invention include but are not limited to improved image quality, increased channel capability, reduced electromagnetic interference, immunity of optical signals and improved bandwidth capacity of the optical cables.

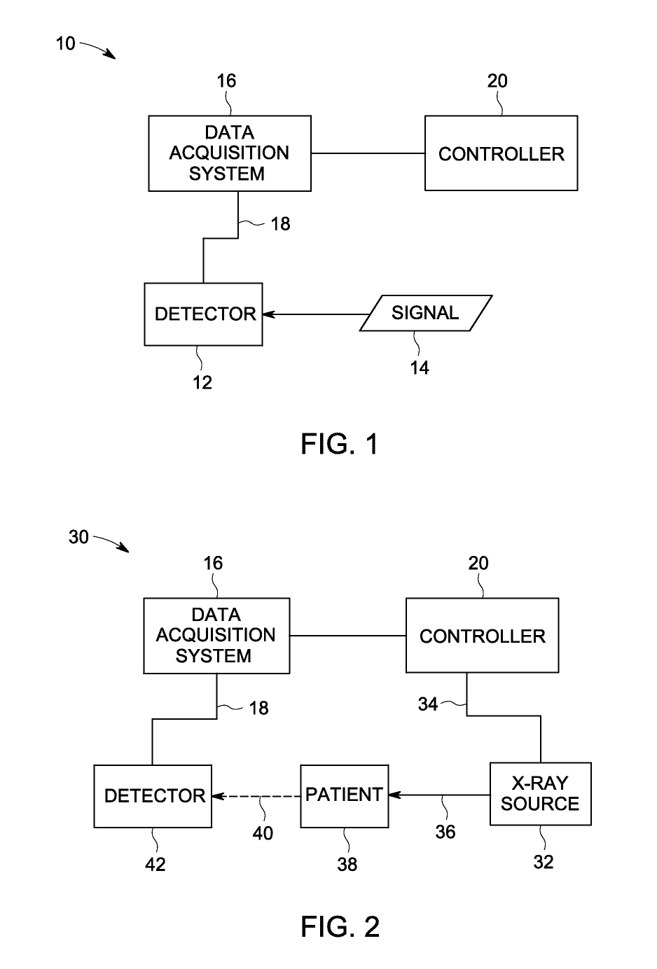

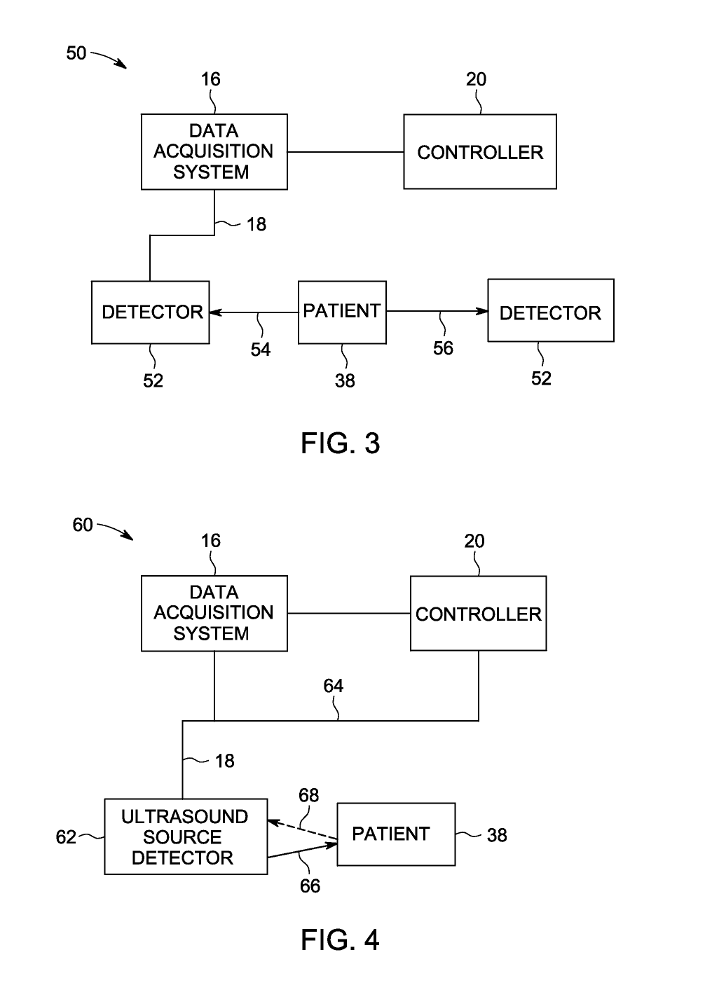

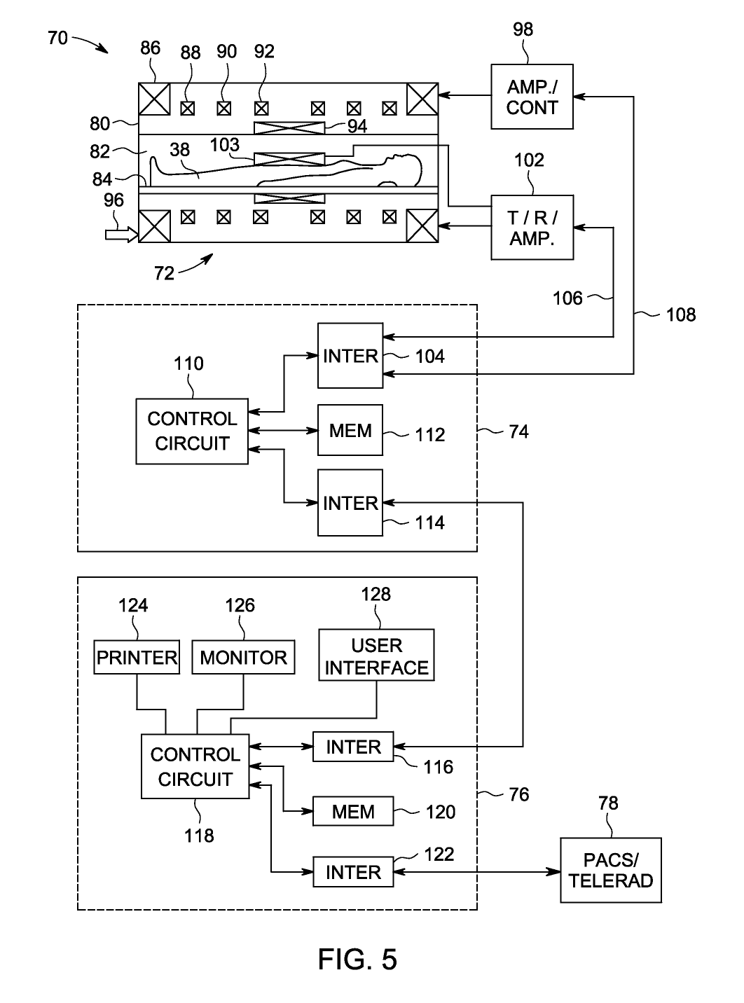

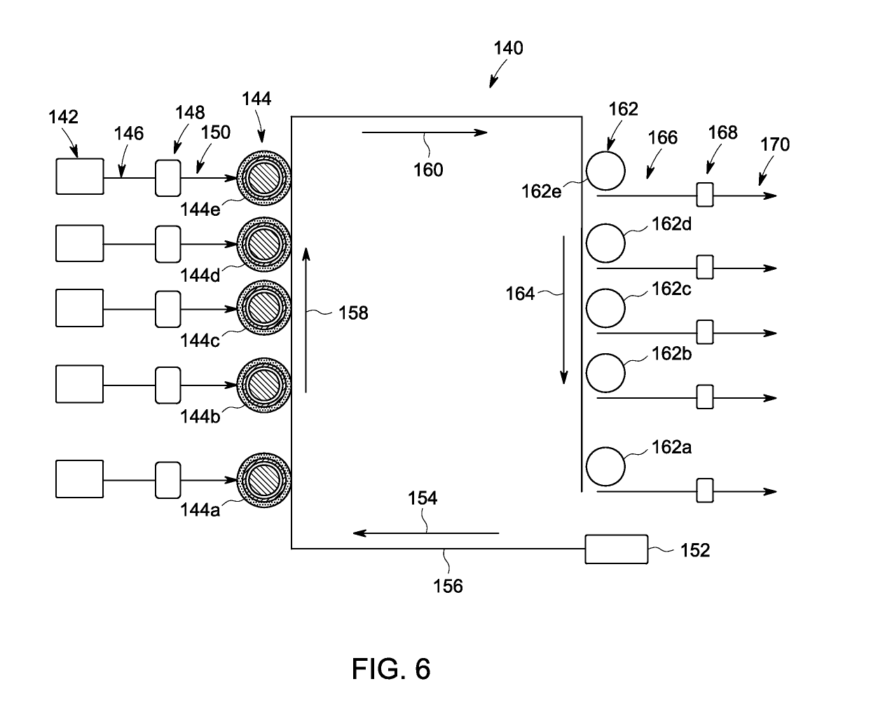

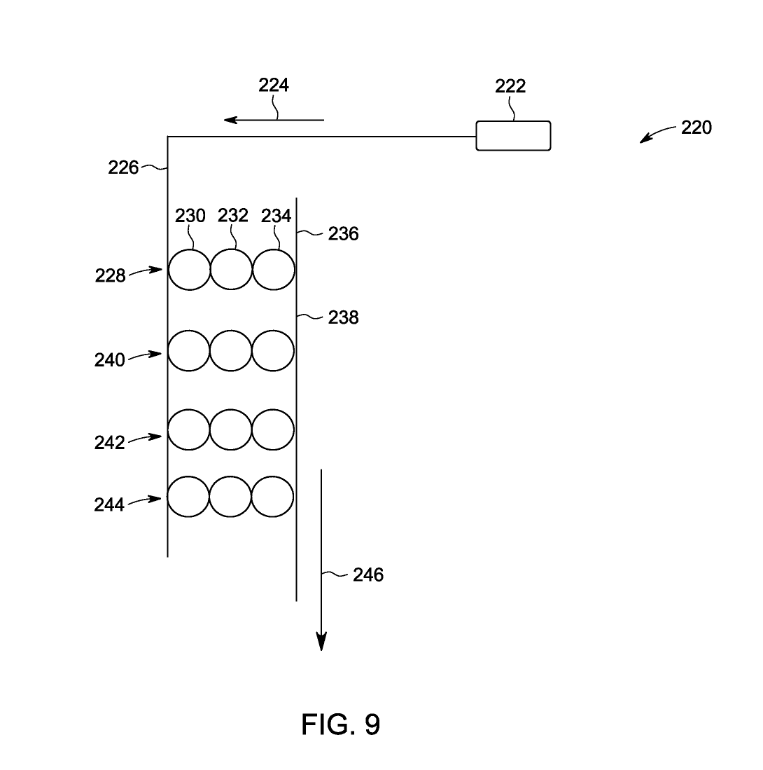

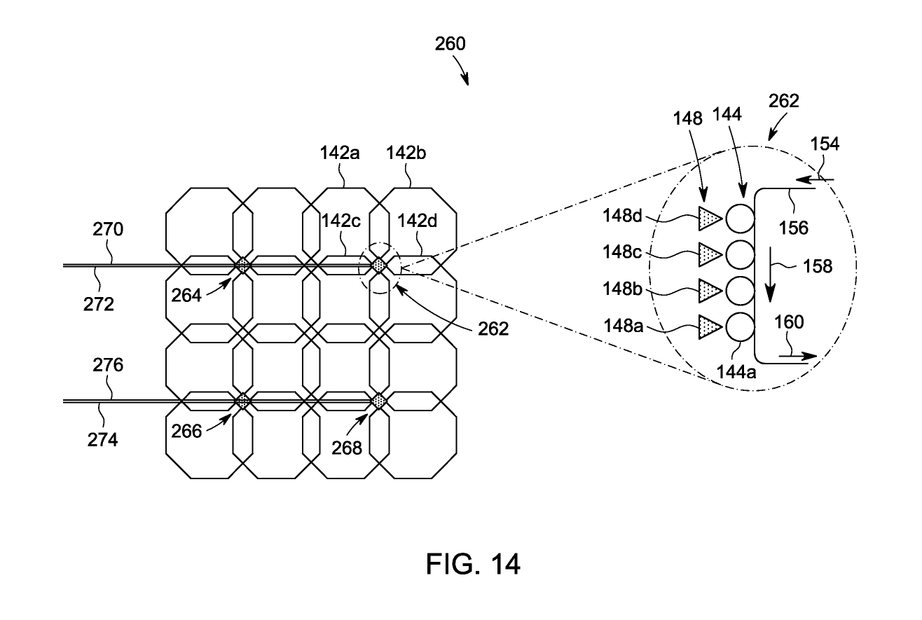

It should be noted that the present approaches may be utilized in a variety of imaging contexts, such as in medical imaging, product inspection for quality control, and for security inspection, to name a few. However, for simplicity, examples discussed herein relate generally to medical imaging, particularly magnetic resonance imaging. However, it should be appreciated that these examples are merely illustrative and made to simplify explanation and that the present approaches may be used in conjunction with any of the disclosed imaging technologies as well as in different contexts than medical imaging. Specifically, FIGS. 1-5 discuss embodiments of medical imaging systems that may benefit from the incorporation of nanophotonic modulators for optical data and/or power transmission, with FIG. 1 being directed towards a general imaging system, FIG. 2 being directed towards an X-ray imaging system such as a computed tomography (CT)/C-arm imaging system, FIG. 3 being directed towards a PET/SPECT imaging system, FIG. 4 being directed towards an ultrasound imaging system, and FIG. 5 being directed towards an MRI system. Further, embodiments of the nanophotonic modulators and their integration into such imaging systems is described in further detail in the context of the MRI system of FIG. 5 with respect to FIGS. 6-8. Varying arrangements of the modulators are discussed with respect to FIGS. 9-13, and an embodiment of the integration of the nanophotonic modulators with the RF coils of the MRI system of FIG. 5 is discussed with respect to FIGS. 14-16.

With the foregoing in mind, FIG. 1 provides a block diagram illustration of a generalized imaging system 10. The imaging system 10 includes a detector 12 for detecting a signal 14. The detector 12 may include one or more arrays of detection elements such as photodiodes, coils, sonic transducers, scintillators, photomultiplier tubes, and so on, to detect the signal 14. The signal 14 may generally include some form of electromagnetic or other radiation, such as gamma rays, X-rays, sonic echoes, RF, sound waves, and the like. Generally, the more detection elements in the detector 12, the greater its ability to spatially resolve such radiation, leading to higher quality images. As noted above, however, each detection element may require a separate channel, which can substantially increase cabling as well as spatial and energy requirements.

The detector 12 generates electrical signals in response to the detected radiation, and these electrical signals are sent through their respective channels to a data acquisition system (DAS) 16 via data link 18. In a typical configuration, data link 18 includes a plurality of electrical wires that must be bundled, insulated, thermally maintained, and so on. In accordance with the present approaches, however, the data link 18 may advantageously include fewer lines, for example a single waveguide line, or a few optical lines, connecting the detector 12 with the DAS 16. Further, such an optical interface may transmit the entire collection of data from all of the channels exiting the detector 12. The data link 18 in accordance with present embodiments may include, as an example, a plurality of modulators having optical resonators (e.g., micro-ring resonators) that encode each electrical signal (i.e., each channel) received from the detector with a specific wavelength of light. The wavelengths of light may be multiplexed and transmitted towards the DAS 16, for example via one or more waveguide lines. Towards the end of the data link 18 (i.e., towards the DAS 16), the waveguide line may encounter a series of demultiplexers that are tuned to specific wavelengths at which each channel is optically encoded. That is, each optical resonator on the multiplexing side is tuned to a specific optical resonator on the demultiplexing side. Each channel is converted back into an electrical signal using a transducer such as a photodetector, and provided to the DAS 16. Such an approach is discussed in further detail with respect to FIG. 6. However, it should be noted that the optical transmission of at least data from the detector 12 to the DAS 16 will typically require less cost, less energy, less physical space, and so on.

Once the DAS 16 acquires the electrical signals, which may be analog signals, the DAS 16 may digitize or otherwise condition the data for easier processing. For example, the DAS 16 may filter the image data based on time (e.g., in a time series imaging routine), may filter the image data for noise or other image aberrations, and so on. The DAS 16 then provides the data to a controller 20 to which it is operatively connected. The controller 20 may be an application-specific or general purpose computer with appropriately configured software. The controller 20 may include computer circuitry configured to execute algorithms such as imaging protocols, data processing, diagnostic evaluation, and so forth. As an example, the controller 20 may direct the DAS 16 to perform image acquisition at certain times, to filter certain types of data, and the like. Additionally, the controller 20 may include features for interfacing with an operator, such as an Ethernet connection, an Internet connection, a wireless transceiver, a keyboard, a mouse, a trackball, a display, and so on.

Keeping such an approach in mind, FIG. 2 is a block diagram illustrating an embodiment of an X-ray imaging system 30 that may incorporate various nanophotonic features in accordance with the approaches noted above. The X-ray imaging system 30 may be an inspection system, such as for quality control, package screening, and safety screening, or may be a medical imaging system. In the illustrated embodiment, system 30 is an X-ray medical imaging system such as a CT or C-arm imaging system. In regards to the configuration of system 30, it is similar in design to the generalized imaging system 10 described with respect to FIG. 1. For example, the system 30 includes the controller 20 operatively connected to the DAS 16, which allows the controlled acquisition of image data via a detecting array. In system 30, to enable the collection of image data, the controller 20 is also operatively connected to a source of X-rays 32, which may include one or more X-ray tubes.

The controller 20 may furnish a variety of control signals, such as timing signals, imaging sequences, and so forth to the X-ray source 32 via a control link 34. In some embodiments, the control link 34 may also furnish power, such as electrical power, to the X-ray source 32 via control link 34. In accordance with present embodiments, the control link 34 may incorporate one or more photonic data and/or power delivery systems, as will be described in detail below. Generally, the controller 20 will send a series of signals to the X-ray source 32 to begin the emission of X-rays 36, which are directed towards a subject of interest, such as a patient 38. Various features within the patient 38, such as tissues, bone, etc., will attenuate the incident X-rays 36. The attenuated X-rays 40, having passed through the patient 38, then strike a detector 42, such as a detector panel or similar detector array to produce electrical signals representative of a corresponding data scan (i.e., an image). The detector 42, in the case of digital detectors, may include hundreds or thousands of detecting elements such as scintillators, diodes, and so forth. As noted above, each detecting element may require a single channel for data transmission, which may limit the number of detecting elements within the detector 42. However, in accordance with present embodiments, they may be optically modulated, multiplexed, transmitted through the data link 18, and demultiplexed. Accordingly, the present embodiments may also allow for a reduction in electrical wiring and associated features in coupling at least the detector 42 with the DAS 16.

In some imaging contexts, it can be important to transfer information that may be acquired substantially simultaneously, so as to correlate one acquired signal with another. One such imaging context is PET imaging systems, an embodiment of which is illustrated in FIG. 3. Specifically, FIG. 3 illustrates a block diagram of an embodiment of a PET imaging system 50 having the data link 18 between a detector array 52 and the DAS 16. In PET imaging, the detector 52 is generally configured to surround the patient 38. Specifically, the detector 52 of the PET system 50 typically includes a number of detector modules arranged in one or more rings. For simplicity, the illustrated embodiment depicts two areas of the detector 52 disposed approximately 180 degrees apart so as to substantially simultaneously capture pairs of gamma rays that are emitted during imaging, as discussed below. It should be noted that in other embodiments, such as in SPECT embodiments, the detector 52 may be disposed as a ring, but a single photon is detected rather than a coincident photon pair as in PET. The detector 52 detects photons generated from within the patient 38 by a decaying radionuclide. For example, a radionuclide may be injected into the patient 38 and may be selectively absorbed by certain tissues (e.g., tissues having abnormal characteristics such as a tumor). As the radionuclide decays, positrons are emitted. The positrons may collide with complementary electrons (e.g., from atoms within the tissue), which results in an annihilation event. The annihilation event, in PET, results in the emission of a first and second gamma photon 54, 56. The first and second gamma photons 54, 56 may strike the detectors 52 at separate areas approximately 180 degrees from one another. Typically, the first and second gamma photons 54, 56 strike the detectors 52 at approximately the same time (i.e., are coincident), and are correlated with one another. The origin of the annihilation event may then be localized. This is repeated for many annihilation events, which generally results in an image in which the contrast of the abnormal tissues appear enhanced. In this regard, it should be noted that the detector 52 may advantageously include a plurality of detecting elements so as to allow high spatial resolution to produce an image of sufficient quality. For example, by detecting a number of gamma ray pairs, and calculating the corresponding lines traveled by these pairs, the concentration of the radioactive tracer in different parts of the body may be estimated and a tumor, thereby, may be detected. Therefore, accurate detection and localization of the gamma rays forms a fundamental and foremost objective of the PET system 50. Advantageously, the present embodiments provide for the utilization of an increased number of data channels from the detector 52 to the DAS 16 via data link 18. As noted above, this may allow the use of an increased number of detection elements compared to fully electrical configurations, increasing the resolution and image quality resulting from such PET scans.

In some embodiments, the detector may be integral with the source, such that a single imaging component (e.g., a probe) produces sonic energy and directs it towards the patient, followed by detection of any resulting sonic waves that are echoed. An example of such an implementation is an ultrasound imaging system, an embodiment of which is illustrated in FIG. 4. Specifically, FIG. 4 illustrates an embodiment of an ultrasound imaging system 60 having the both the DAS 16 and the controller 20 operatively connected to an ultrasound source/detector 62 (i.e., an ultrasound probe). The ultrasound source/detector 62 may be optically connected via the data link 18 to the DAS 16 in accordance with the approaches described above. Additionally, the controller 20 may be optically connected to the ultrasound source/detector 62 via control line 64 so as to furnish control signals, power, and so forth to command the acquisition of patient data. For example, the ultrasound source/detector 62 may include a patient facing or contacting surface that includes a transducer array having a plurality of transducers. Each transducer may be capable of producing ultrasonic energy 66 when energized by a pulsed waveform as directed by the controller 20. Ultrasonic energy 68 is reflected back toward the transducer ultrasound source/detector 62, such as from the patient 38, and is converted to an electrical signal, which is utilized to construct a useful image. As in the other modalities discussed above, the resolution of the resulting images may be directly dependent upon the number of detection elements within the probe.

It should be noted that in such an imaging context, such as when the source and detector are handheld, that spatial availability may be greatly limited when generally compared to other modalities. Accordingly, the present approaches provide for power and data to be furnished the ultrasound source/detector 62 via link 64 in an optical manner. Additionally, the transmittance of image data from the ultrasound source/detector 62 to the DAS 16 may be optical over data link 18.

Such power and data transmission may also be applied to MRI systems, wherein specific imaging routines are initiated by a user (e.g., a radiologist). An embodiment of such a system is illustrated in FIG. 5, which depicts a magnetic resonance imaging system 70 including a scanner 72, a scanner control circuit 74, and a system control circuit 76. System 70 additionally includes remote access and storage systems or devices as picture archiving and communication systems (PACS) 78, or other devices such as teleradiology equipment so that data acquired by the system 70 may be accessed on- or off-site. While the MRI system 70 may include any suitable scanner or detector, in the illustrated embodiment, the system 70 includes a full body scanner 72 having a housing 80 through which a bore 82 is formed. A table 84 is moveable into the bore 82 to permit a patient 38 to be positioned therein for imaging selected anatomy.

Scanner 72 includes a series of associated coils for producing one or more controlled magnetic fields and for detecting emissions from gyromagnetic material within the anatomy of the patient 38 being imaged. A primary magnet coil 86 is provided for generating a primary magnetic field that is generally aligned with the bore 82. A series of gradient coils 88, 90, and 92 permit controlled magnetic gradient fields to be generated during examination sequences. A radio frequency (RF) coil 94 is provided for generating radio frequency pulses for exciting the gyromagnetic material, such as for spin preparation, relaxation weighting, spin perturbation or slice selection. A separate receiving coil or the same RF coil 94 may receive magnetic resonance signals from the gyromagnetic material during examination sequences.

The various coils of scanner 72 are controlled by external circuitry to generate the desired field and pulses, and to read emissions from the gyromagnetic material in a controlled manner. In one embodiment, a main power supply 96 is provided for powering the primary field coil 86. Driver circuit 98 is provided for pulsing the gradient field coils 88, 90, and 92. Such a circuit typically includes amplification and control circuitry for supplying current to the coils as defined by digitized pulse sequences output by the scanner control circuit 74. Another control circuit 102 is provided for regulating operation of the RF coil 94. Circuit 102, in some embodiments, may include a switching device for alternating between the active and passive modes of operation, wherein the RF coils transmits and receives signals, respectively. However, in the illustrated embodiment, circuit 102 is in communication with a receive coil array 103, such as an array that may be placed on the patient 38. In accordance with the present disclosure, the receive coil array 103 includes an optical interface with the circuit 102, for example for the shuttling of data, the provision of control signals, and so forth. Circuit 102 also includes amplification circuitry for generating the RF pulses and receiving circuitry for processing magnetic resonance signals received by the receiver array 103. The manner in which the transfer of power and/or data between the coils, amplifiers, and circuit 102 is described with further detail with respect to FIGS. 6-8.

Scanner control circuit 74 includes an interface circuit 104 which outputs signals for driving the gradient field coils 88-92 and the RF coil 94 and for receiving the data representative of the magnetic resonance signals produced in examination sequences. The interface circuit 104 is also coupled to a control circuit 110. The control circuit 110 executes the commands for driving the circuit 102 and circuit 98 based on defined protocols selected via system control circuit 76. Control circuit 110 also serves to receive the magnetic resonance signals and performs subsequent processing before transmitting the data to system control circuit 76. Scanner control circuit 74 also includes one or more memory circuits 112 which store configuration parameters, pulse sequence descriptions, examination results, and so forth. Interface circuit 114 is coupled to the control circuit 110 for exchanging data between scanner control circuit 74 and system control circuit 76. Such data will typically include selection of specific examination sequences to be performed, configuration parameters of these sequences, and acquired data which may be transmitted in raw or processed form from scanner control circuit 74 for subsequent processing, storage, transmission and display.

System control circuit 76 includes an interface circuit 116 which receives data from the scanner control circuit 74 and transmits data and commands back to the scanner control circuit 74. The interface circuit 116 is coupled to a control circuit 118 which may include a CPU in a multi-purpose or application specific computer or workstation. Control circuit 118 is coupled to a memory circuit 120 to store programming code for operation of the MRI system 70 and to store the processed image data for later reconstruction, display and transmission. An additional interface circuit 122 may be provided for exchanging image data, configuration parameters, and so forth with external system components such as remote access and storage devices 78. Finally, the system control circuit 118 may include various peripheral devices for facilitating operator interface and for producing hard copies of the reconstructed images. In the illustrated embodiment, these peripherals include a printer 124, a monitor 126, and user interface 128 including devices such as a keyboard or a mouse.

Keeping in mind the operation and general configuration of the MRI system 70 of FIG. 5, the present approaches to nanophotonic data delivery will be described in the context of magnetic resonance (MR) data transferred from the RF receiving coil array 103 to image processing circuitry, for example scanner control circuitry 74 and/or system control circuitry 76. Accordingly, to facilitate the discussion of such nanophotonic data delivery, a nanophotonic system 140 incorporating features for the optical transmission of data from an array RF receiving coils 142, which may be similar to the array 103 of FIG. 5, to image processing circuitry is described with respect to FIG. 6. It should be noted that all or a part of the nanophotonic system 140 may be integrated on a single chip or a plurality of chips, and that the data that is transferred may be analog and/or digital.

In the illustrated embodiment, the nanophotonic system 140 is depicted as including an array of optical modulators 144 that are configured to convert electrical signals (e.g., digital or analog signals) representative of magnetic resonance data into optical signals. In a general sense, each of the optical modulators 144 may include one or more optical resonators configured to operate at a distinct wavelength from each of the other optical modulators. Specifically, each the modulators 144 modulate a distinct subset of photons contained within a beam of light so as to encode the subset of photons with respective sets of data to produce encoded subsets of photons. Each subset of photons may be so categorized in that it may have a plurality of photons having similar wavelengths (e.g., within a few nm of each other), the same wavelengths, the same polarizations, or in that the plurality of photons arrive at the modulator at substantially the same time. As defined herein, the subsets of photons may include a plurality of photons such that they may exhibit collective behavior, as opposed to behavior reminiscent of single quanta. The wavelength control exhibited by the resonators is obtained via lithography or via thermal tuning. In the illustrated embodiment, the system 140 may employ any or a combination of micro-ring resonators, arrayed waveguide gratings, and/or Mach-Zender interferometers for the purpose of performing optical multiplexing and/or demultiplexing on the subsets of photons contained within a beam of light. Again, each resonator/photonic element is designed to operate at a unique optical wavelength.

During operation of the nanophotonic system 140, the RF coils 142 each receive respective MR signals. The MR signals are then converted into electrical signals 146 (e.g., analog or digital), which are directed to their respective amplifiers 148. As an example, the amplifiers may be low noise amplifiers (LNAs) that are driven using between about 0.005 Watts (W) and 1 W of energy (e.g., between about 5 mW and about 500 mW, or about ⅓ W). In some configurations, the LNAs may generate MR-compatible low noise within a narrow bandwidth around the Larmor frequency (typically at approximately either 64 MHz or 128 MHz for hydrogen nuclei at 1.5 T and 3 T respectively, but potentially at other frequencies corresponding to ³¹P, ¹³C, or other nuclei) so as to avoid the introduction of noise into MR signals received at the coils 142. The amplifiers amplify the electrical signals 146, which are then sent as amplified electrical signals 150 to the array of optical modulators 144, for example as amplified analog signals or amplified digital signals.

In a process occurring substantially simultaneously to the transmission of data to the array of optical modulators 144, a source of light 152, such as one or more LEDs, diode lasers, micro ring lasers, or the like, sends an optical beam 154 through a waveguide 156, for example a fiber optic conduit. The optical beam 154 may include one or a plurality of optical wavelengths. That is, the optical beam may include subsets of photons, with each subset having respective polarizations, or wavelengths, and so forth. While the illustrated embodiment depicts the system 140 as including a single waveguide, it should be noted that the use of more than waveguide is contemplated herein, such as a series of waveguides running to a plurality of optical modulators, or a waveguide used for transmission to the optical modulators and a separate waveguide used as a drop line to carry modulated optical signals from the modulators. Such embodiments are discussed with respect to FIGS. 9-13 below.

As illustrated in FIG. 6, the optical beam 154 is transmitted along the waveguide 156 and encounters the array of optical modulators 144. The waveguide 156, in a general sense, may be a single or multi-modal optical fiber, and may include only one or multiple optical fibers, or may be a channel etched into a silicon chip. Additionally, the waveguide line 156 may be a silica-based waveguide material, or may include any one or a combination of waveguide materials known in the art, such as silica, fluorozirconate, fluoroaluminate, chalcogenide, sapphire, and/or plastic materials. As the optical beam 154 encounters the array of optical modulators 144, each modulator encodes a portion of the optical beam 154 with MR data received at their respective coils 142, resulting in an optical beam 158 that becomes increasingly modulated (e.g., as it encounters more optical modulators). For example, the optical beam 154 may include a plurality of wavelengths (or polarizations or times) to which one of the plurality of optical modulators 144 may be tuned. In accordance with the present approaches, the wavelengths that are able to be differentially encoded by the modulators 144 may be separated by as little as a few nanometers (nm), or as much as a micron. In some embodiments, the wavelengths to which the optical modulators 144 are tuned may be in the range of about 1520 nm to about 1570 nm (i.e., about 1.57 μm). In the non-limiting illustrated embodiment, the system 140 includes five different optical modulators, modulators 144a, 144b, 144c, 144d, and 144e, which may be tuned to respective wavelengths contained in the optical beam 158 (e.g., λₐ, λ_{b}, λ_{c}, λ_{d}, and λₑ, respectively). In this way, optical modulator 144a may encode a wavelength λₐ with magnetic resonance data received from its respective RF coil, modulator 144b may encode a wavelength λ_{b} with magnetic resonance data received from its respective RF coil, and so on. In the illustrated embodiment, after the optical beam 158 has encountered the optical modulator 144e, an optical beam 160 that has been fully encoded with MR data from the RF receiving coils 142 may be transmitted through the waveguide 156. That is, the optical beam 160 is multiplexed with the data captured by the RF coils 142. Accordingly, it should be noted that the process described above may be performed substantially continuously as MR data are collected at the RF coils 142.

Once the fully encoded optical beam 160 has been produced, the optical fiber 156 transmits the beam 160 along a path that encounters a plurality of optical resonators 162 that are generally configured to demultiplex the optical beam 160. Therefore, as the optical beam 160 encounters the plurality of optical resonators 162, an optical beam 164 may be produced that becomes increasingly demultiplexed as it encounters the resonators 162. For example, the optical beam 160 may encounter optical resonators 162a, 162b, 162c, 162d, and 162e, which, as with the optical modulators 144a-144e, are tuned to wavelengths λₐ, λ_{b}, λ_{c}, λ_{d}, and λₑ, respectively. In the illustrated embodiment, the first optical resonator to be encountered is resonator 162e, which may be tuned to wavelength λₑ. The optical beam 164 then encounters resonator 162d, which may be tuned to a different wavelength, for example λ_{d}, and so on, until reaching the last optical resonator 162a. It should be noted that while the optical beam 160 is illustrated as encountering the optical resonators in the order described above, the present approaches also contemplate the use of any order of demultiplexing, allowing the resonators 162 to be tuned to any desired wavelength and any desired multiplexing/demultiplexing order.

Upon demultiplexing at each respective wavelength as described above, each optical resonator 162 produces a respective optical signal 166, which may generally include the wavelength or wavelengths to which the resonator is tuned. In this way, the optical signal 166 produced at resonator 162e includes wavelength λₑ, and so on. Of course, the optical signals 166 may be transmitted along respective waveguide lines in which they are directed to photodetector arrays 168 to produce respective electrical signals 170. The detectors 168 may include photodetectors such as photodiode arrays, Germanium waveguide integrated detectors, or any photodetector that is capable of acting as a transducer to generate the electrical signals 170 from the optical signals 166. The electrical signals 170 that are produced at the photodetectors 168 are representative of the MR data that is detected at the RF coils 142. Accordingly, the electrical signals 170 are sent to processing circuitry, such as scanner control circuitry 74 and/or system control circuitry 76 to allow the MR data to be processed, stored, and/or interpreted.

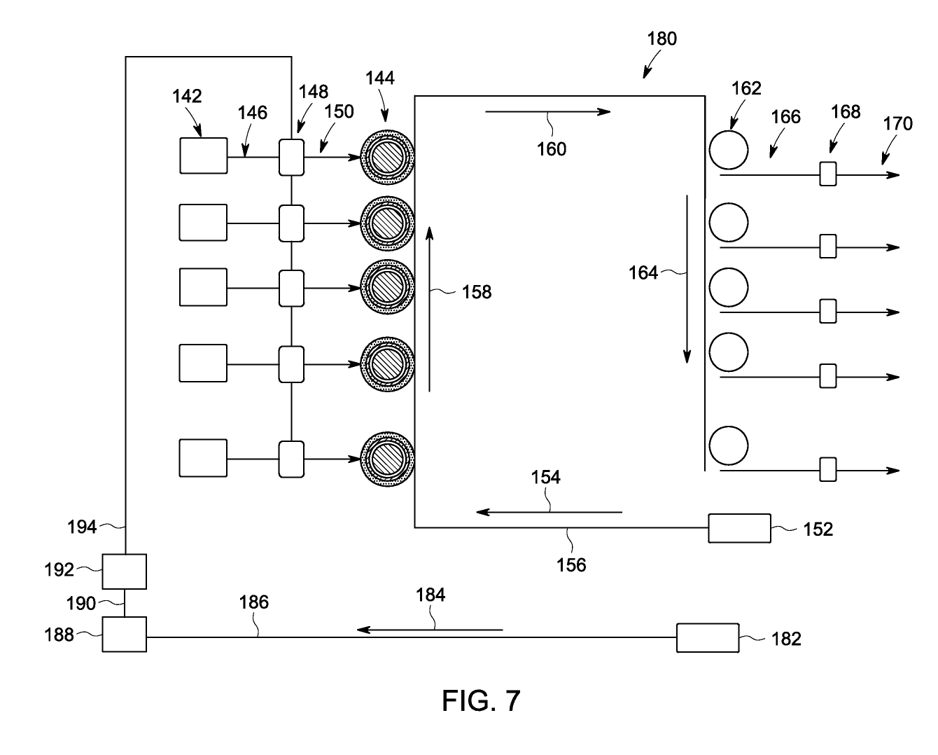

While the embodiment illustrated in FIG. 6 includes features configured to optically transfer data from the RF coils 142 to one or more processing circuits of the MR system 70, FIG. 7 illustrates an embodiment of a system 180 configured to provide optical power to the array of amplifiers 148 that drive the modulators 144. System 180 includes features for both optical power delivery and optical data transmission. However, in some embodiments, only optical power delivery may be provided. Indeed, in some embodiments, the features described herein relating to photonic power delivery may be implemented on a single chip, for example a silicon chip (e.g., a silicon on insulator (SOI) chip). Moreover, the features described above relating to photonic data transmission may be implemented on the same or a separate chip. Accordingly, the approaches described herein may be fully implemented on a single chip, or on multiple chips. Keeping in mind the operation of the system 140 described in FIG. 6, the system 180 illustrated in FIG. 7 includes, among other features, an optical power source 182 configured to output an optical beam 184 for eventual power delivery to the amplifier array 148. Generally, the optical power source 182 includes one or more lasers having the capability to substantially continuously output a sufficient amount of power so as to drive the amplifiers 148, and at least partially drive the optical modulators 144. In accordance with the present embodiments, each of the amplifiers 148 may utilize between about 0.3 Watts (W) and about 1 W. However, it should be noted that the present approaches are also applicable to amplifiers using more or less power. Accordingly, the optical power source 182 may include one or more lasers capable of outputting up to about a few milliwatts each (e.g., about 1 mW, 5 mW, 10 mW etc).

The optical beam 184 produced by the optical power source 182 may include one or a number of wavelengths which may be determined by the configuration and/or number of light sources within the optical power source 182. As an example, the optical beam 184 may include one or more visible wavelengths, such as from a broadband laser and/or multiple lasers operating at respective bandwidths and wavelengths. The optical beam 184 is directed through a waveguide 186 to a transducer 188. The waveguide 186 may be a silica-based waveguide material, or may include any combination of waveguide materials known in the art, such as silica, fluorozirconate, fluoroaluminate, chalcogenide, sapphire, and/or plastic materials.

In a general sense, the transducer 188 receives the optical beam 184 and produces an electrical signal 190 as a result. The transducer 188 may be disposed on one or more of the coils 142 or may be separate from the coils 142, and may include a photodiode, or any photodetector that produces an electrical signal upon photo detection, such as a photomultiplier tube (PMT) or the like. In one embodiment, the transducer 188 may be a silicon-based diode operating at one or more visible wavelengths. Moreover, the transducer 188 may be configured to dissipate at least a portion of the heat generated by the reception of the optical beam 184.

Once the transducer 188 produces the electrical signal 190, it is provided to a switch-mode power supply 192. The switch-mode power supply 192 is generally configured to condition the electrical signal 190 so as to provide a conditioned electrical signal 194 that is compatible for use with the amplifiers 148 and the modulators 144. For example, the switch mode power supply 192 may convert AC and/or DC voltages and generate a regulated DC voltage having a power suitable for use with the electronics (e.g., coils 142, amplifiers 148) and/or modulators 144 of system 180. As illustrated in FIG. 7, the conditioned electrical signal 194 is provided at least to the amplifiers 148 to provide the power used for amplification. As noted above, in some embodiments the electrical signal 194 may also be provided to the modulators 144.

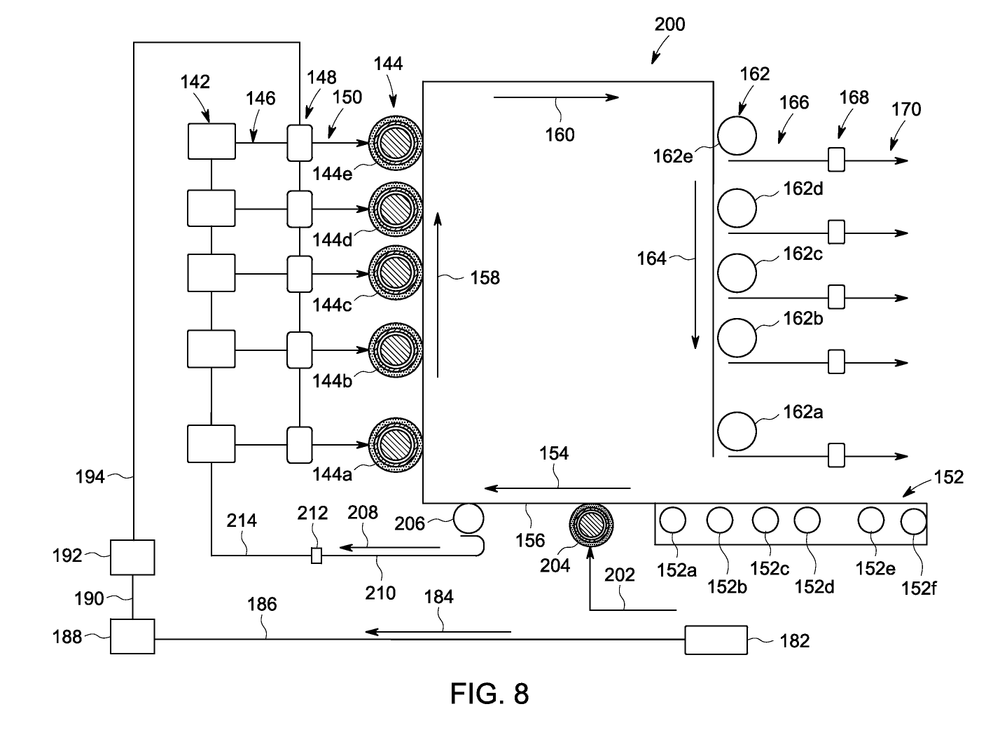

In addition to the photonic power delivery and photonic data transmission features described above with respect to FIGS. 6 and 7, the present approaches also provide a system 200, illustrated in FIG. 8, for the photonic delivery of control signals to the coils 142. Accordingly, the system 200 illustrated in FIG. 8 generally provides a substantially complete optical interface to the features utilized for receiving MR signals within the MRI system 70 of FIG. 5. Thus, keeping in mind the features and operation of the systems 140 and 180 described with respect to FIGS. 6 and 7, respectively, the system 200 includes features for optically modulating one or more coil control signals 202, and for optically delivering the control signals to the coils 142.

To allow the system 200 to optically deliver the control signals to the coils 142, in addition to the optical modulation of the MR signals received at the coils 142, the optical source 152 as illustrated includes a plurality of micro ring lasers 152a, 152b, 152c, 152d, 152e, and 152f. The micro-ring lasers are formed by integrating an optical gain medium on a transparent optical cavity. The cavity can be a either a microring/microdisk or a 1D Bragg grating. Alternatively, an optical cavity with nonlinear optical processes may be used to produce a comb of optical wavelengths. Specifically, each micro ring laser is configured to be tuned to a respective optical modulator 144 and a respective demultiplexing optical resonator 162. For example, micro ring laser 152a is tuned so as to produce λₐ, which, as described above, is the wavelength at which the modulator 144a and the resonator 162a operate. It will be appreciated upon review of FIG. 8 that the number of micro ring lasers generally exceeds the number of optical modulators 144 and optical resonators 162. Generally, the additional micro ring laser(s), which in the illustrated embodiment includes micro ring laser 152f, is configured to produce one or more additional wavelengths (λ_{f}) that is tuned to an optical modulator 204 configured to modulate the coil control signal 202.

Therefore, during operation of the system 200, in addition to the acts described above with respect to FIGS. 6 and 7, the electrical coil control signal 202 is modulated into an optical signal, which becomes part of the optical beam 154. As the optical beam 154 proceeds through waveguide 156, it encounters a demultiplexing optical resonator 206. As the optical beam 154 encounters the optical resonator 206, an optical signal 208 is produced (i.e., demultiplexed from optical beam 154) that is representative of the coil control signal 202. The optical signal 208 is transferred via one or more optical fibers 210 to a transducer 212, which may be a photodiode or the like. The transducer 212 converts the optical beam 208 representative of the coil control signal 202 back into the electrical domain. Accordingly, an electrical signal 214, which may be the same as the electrical coil control signal 202, is produced and is provided to the coil array 142. In this way, the electrical signal 214 may control operation of the coil array 142. It should be noted that while the illustrated embodiment provides one electrical signal 214 being provided to the coil array 142, that each channel, i.e., each coil, may have a distinct and separate set of modulator 204, resonator 206, and transducer 212. Thus, any one or a combination of the modulator 204, resonator 206, and transducer 212 may be disposed directly on any one or a combination of the coils, such that the number of modulators 204, and/or resonators 206, and/or transducers 212 (and any associated waveguides) is equaled by the number of channels.

It should be noted that any of the optical modulators described herein may be implemented using one or multiple optical resonators. For example, to achieve a suitable dynamic contrast ratio, suitable linearity, or the like, it may be desirable to configure the modulators in a similar manner to optical filters, wherein multiple resonators are utilized. An example of such an embodiment of a system 220 including multiple resonators for each modulator is illustrated with respect to FIG. 9. Specifically, FIG. 9 includes a light source 222, which may have a similar configuration to the light source 152 of FIGS. 6-8. The light source 222 produces one or more optical beams 224 which are carried along a first waveguide 226 and may encounter the electrical MR signals described above with respect to FIG. 6.

The optical beam 224 then encounters a modulator 228 configured to convert the electrical signal representative of MR data received at one of the RF coils to the optical domain, and which includes a plurality of resonators 230, 232, 234. Specifically, borrowing from the wavelength-identifying convention described above, the modulator 228 may be tuned to λₐ. Thus, each of the resonators 230, 232, 234 is tuned to λₐ. After λₐ encounters the last of the resonators (i.e., resonator 234), it is provided to a second waveguide, or a drop line 236. A similar process occurs for the optical beam 224 as it encounters modulators 240, 242, and 244, which may be tuned to other respective wavelengths (i.e., λ_{b}, λ_{c}, and λ_{d}). In this way, a multiplexed optical beam 246 carrying MR data is sent to demultiplexing features at a processing area away from the scanner 72.

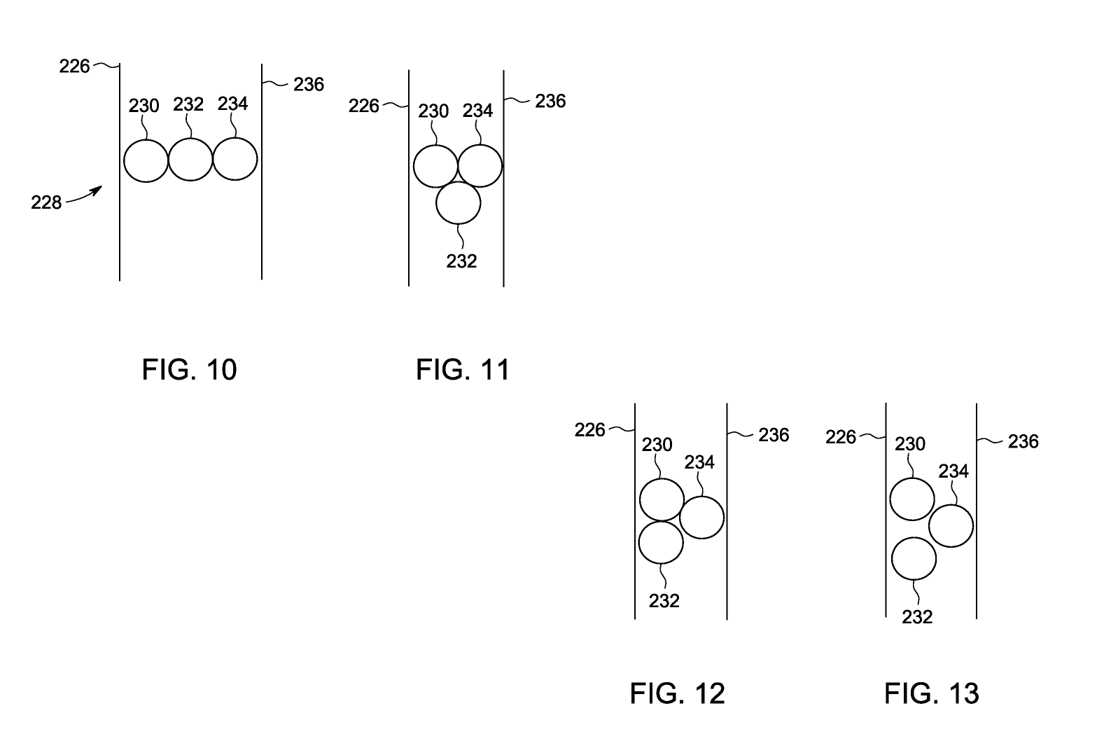

While the embodiment illustrated in FIG. 9 depicts the resonators in a linear fashion, it should be noted that other arrangements of the resonators are contemplated herein, and may be configured using approaches reminiscent of filter design. For example, FIG. 10 illustrates optical resonators in a similar linear configuration to that illustrated in FIG. 9. FIG. 11 illustrates a triangular arrangement wherein two optical resonators 230, 234 connect the waveguides 228 and 236, and one resonator 232 is disposed underneath the other resonators. FIG. 12 illustrates an embodiment wherein resonators 230 and 232 are disposed proximate the first waveguide 226 and the resonator 234 is disposed proximate the drop line 236. FIG. 13 illustrates an embodiment wherein the resonators are disposed in a similar arrangement to that of FIG. 12, but the resonators have increased spacing therebetween to optimize the optical transfer function, or, in some embodiments, do not touch.

As mentioned above, to facilitate the transfer of data from the RF coils 142 and to minimize the number of electrical lines that are utilized in the MR system 70, it may be desirable to dispose one or more of the photonic data transmission features directly on the RF coils 142. An embodiment of such an implementation is illustrated in FIG. 14, which depicts a system 260 wherein four resonant loops share a set of photonic data transmission features. In such an embodiment, it may be desirable for the photonic data transmission features to be integrated onto a single member that is moveable and/or removable within the MR system 70. Additionally, such integration may allow a retrofit onto an existing MR system 70 so as to decrease the number of electrical interconnects, conduits, baluns, and so forth. In the illustrated embodiment, at least a portion of the photonic data transmission features described with respect to FIG. 6 are integrated into single chips 262, 264, 266, and 268. That is, each of the chips includes at least the amplifiers 148, modulators 144, and waveguide 156.

To allow electrical lines and processing equipment to be disposed at a distance so as to avoid interference produced at the MR scanner 72, each chip 262, 264, 266, and 268 may be connected to respective waveguides 270, 272, 274, and 276. In this way, the waveguides 270, 272, 274, and 276 allow a distant connection to the light source 152 and/or the demultiplexing resonators 168. As illustrated and mentioned above, four of the resonant coils 142 may be connected to a single chip. With respect to chip 262, it is configured to interface with resonant coils 142a, 142b, 142c, and 142d, each of which may be matched to their respective amplifiers. In this way, resonant coil 142a provides its electrical signal representative of MR data to amplifier 148a, which in turn provides its amplified electrical signal to optical modulator 144a, and so on.

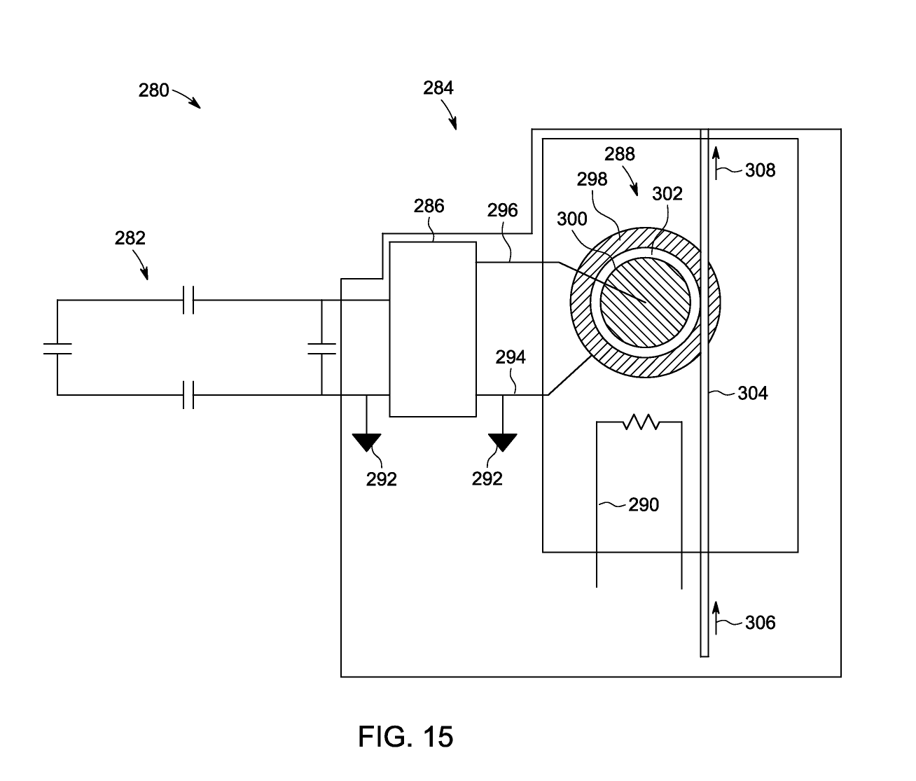

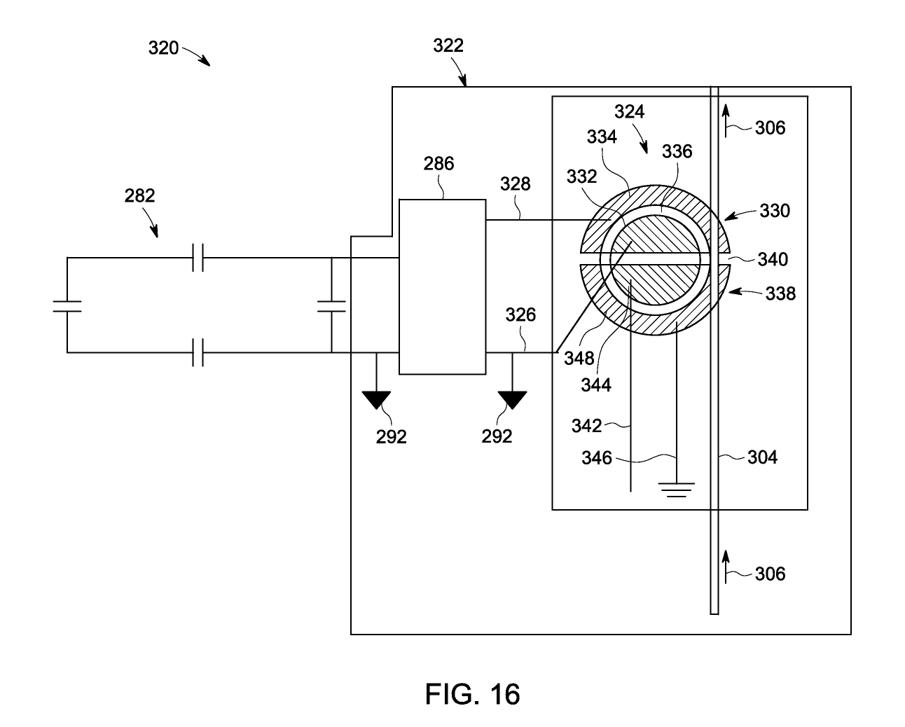

The manner in which the optical modulators 144 are configured to receive information from the RF coils 142 and interface with optical beams is described in further detail with respect to FIGS. 15 and 16. Specifically, FIG. 15 provides an embodiment of an optical modulator arrangement that is thermally tunable, and FIG. 16 provides an embodiment of a split-ring optical modulator arrangement that is electrically tunable. Referring now to FIG. 15, an embodiment of a system 280 for modulating MR data received from one or more resonant coils 282 is provided. A chip 284 is provided that includes, among other features, an amplifier 286, an optical modulator 288, and a heating element 290. The operation of the system 280 is described below.

It should be noted that the resonant coil 282 is generally configured to receive faint RF signals from nuclear spins within the patient 38 after the spins have been excited by the transmitting RF coil 94 of the scanner 72 (FIG. 5), and the coil 282 receives these signals as the gyromagnetic nuclei return to their equilibrium magnetization. Accordingly, the coil 282 may also have features in addition to those in the illustrated embodiment, such as features used to deactivate the coil 282 during RF transmission, to avoid damaging electrical components when the scanner 72 is transmitting a large amount of RF energy. For example, a micro electromechanical switch (MEMS) device may be disposed on the resonant coil 282, and may prevent the coil 282 from resonating with the RF energy generated by the scanner 72 during the RF transmit pulse.

Thus, during operation, the coil 282 receives an RF signal, which is representative of MR data of the patient 38. The coil 282 then produces an electrical data signal representative of the MR data. The amplifier 286 then amplifies the electrical data signal produced at the resonant coil 282. The amplified electrical data signal is then provided to the optical modulator 288 in the form of an unbalanced electrical signal. In the illustrated embodiment, the electrical signal is unbalanced due to a floating reference ground 292 that is separate from a universal ground of the MR system 70.

Specifically, the amplifier 286 interfaces with the optical modulator 288 via a first connection 294 and a second connection 296. The first connection 294 interfaces with an outer p-region 298 (i.e., a p-type semiconducting region), and the second connection 296 interfaces with an inner n-region 300 (i.e., a n-type semiconducting region) of the optical modulator 288. Thus, the optical modulator 288 may be a PN-type diode, a PIN-type diode, or a multilayered structure such as PINIP device or a MOS (metal oxide semiconductor) capacitor. The p-region 298 and the n-region 300 of the optical modulator 288 are separated from each other by a micro ring resonator 302. The micro ring resonator 302 is the area in which photons having specific wavelengths are modulated by the bias created between the p-region 298 and the n-region 300. Therefore, an optical waveguide 304 (e.g., a waveguide etched into the chip) transmitting an optical beam 306 interfaces with the optical modulator 288, and a subset of optical wavelengths within the optical beam 306 having wavelengths to which the optical modulator 288 is tuned are modulated or encoded with the MR data to produce a modulated or encoded optical beam 308. To allow the optical modulator 288 to encode or modulate only a subset of optical wavelengths within the optical beam 306, the heater 290 adjusts the bias across the modulator 288 by providing thermal energy to all or a portion of the modulator 288. Of course, the optical waveguide 304 may interface with a plurality of optical modulators similar to modulator 288 but having different targeted wavelengths such that the optical beam 304 (and/or beam 308) is able to be multiplexed.

Moving now to FIG. 16, an embodiment of a system 320 employing a chip 322 having a split-ring modulator 324 is provided for producing an optical signal encoded with MR data. The operation of the system 320 is generally similar to the operation of the system 280 on the coil 282 and amplifier side 286. Accordingly, keeping the operation of such features in mind, the operation of the split-ring modulator 324 is described herein.

As above, the amplifier 286 has at least two connections with the split-ring modulator 324. Specifically, the amplifier 286 interfaces with the split-ring modulator 324 via first connection 326 and a second connection 328, with both connections being on a first side 330 of the split-ring modulator 324. In a similar manner to the optical modulator described above, the first connection 326 interfaces with a first inner n-region 332 and the second connection 328 interfaces with a first outer p-region 334, which are separated by a micro ring resonator 336. In this regard, the manner in which the split-ring modulator 324 modulates the optical beam 306 is generally similar to that described above with respect to FIG. 15.

However, in contrast to the optical modulator 288 of FIG. 15, the split-ring modulator 324 has the first side 330 separated from a second side 338 via a split 340. Such discontinuity between the portions of the modulator 324 allows an electrical bias to be placed across the split-ring modulator 324 so as to allow tuning to one or more specific wavelengths for modulation. Thus, a DC bias control 342 is connected to a second inner n-region 344, with a ground 346 being connected to a second outer p-region 348. In this way, a voltage is placed on the second side 338 so as to create a bias across the split-ring modulator 324 to allow wavelength tuning.

This written description uses examples to disclose the invention, including the best mode, and also to enable any person skilled in the art to practice the invention, including making and using any devices or systems and performing any incorporated methods. It should also be understood that the various examples disclosed herein may have features that can be combined with those of other examples or embodiments disclosed herein. That is, the present examples are presented in such as way as to simplify explanation but may also be combined one with another. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A medical imaging system, comprising:
a multiplexed photonic data transfer system, comprising:
an optical modulator configured to receive an electrical signal representative of a set of data and being operable to modulate a subset of photons defined by time, wavelength, or polarization contained within a beam of light so as to encode the photons with the set of data to produce encoded photons;
an optical waveguide interfacing with at least a portion of the optical modulator and configured to transmit the beam of light so as to allow the photons to be modulated by the optical modulator;
an optical resonator in communication with the optical waveguide and configured to remove the encoded photons from the beam of light; and
a transducer optically connected to the optical resonator and configured to convert the encoded photons into the electrical signal representative of the set of data.

2. The system of claim 1, wherein the optical modulator and the optical resonator are tuned to the wavelength of the subset of photons.

3. The system of claim 1, wherein the optical modulator comprises a micro ring resonator.

4. The system of claim 1, wherein the optical resonator comprises a microdisc, a microring, or a photonic crystal cavity.

5. The system of claim 1, wherein the transducer comprises a photodiode array.

6. The system of claim 1, comprising a light source configured to produce the beam of light.

7. The system of claim 6, wherein the beam of light comprises a plurality of subsets of photons, each subset having respective wavelengths, and the optical modulator is tuned so as to modulate a first subset of the plurality of subsets of photons contained within the beam of light to produce a first set of encoded photons.

8. The system of claim 7, wherein the first subset of the plurality of subsets of photons are all within a range of wavelengths to which the optical modulator and the optical resonator are tuned.

9. The system of claim 8, comprising additional optical modulators configured to receive electrical signals representative of additional sets of data and being operable to modulate respective subsets of the plurality of subsets of photons having respective wavelengths contained within the beam of light so as to produce additional sets of encoded photons.

10. The system of claim 9, wherein the beam of light is multiplexed upon encountering the optical modulators.

11. The system of claim 10, comprising additional optical resonators tuned to the respective wavelengths of the respective subsets of the plurality of photons.

12. The system of claim 1, wherein the set of data comprises control signal data provided to a magnetic resonance imaging coil.

13. The system of claim 1, wherein the encoded photons are substantially immune to radiofrequency (RF) interference.

14. A medical imaging system, comprising:
a photonic power delivery system, comprising:
a light source being operable to produce a beam of light;
a waveguide coupled to the light source at a first end of the waveguide and configured to transmit the beam of light; and
a transducer coupled to a second end of the waveguide and configured to convert the beam of light into an electrical power signal for powering a component of the medical imaging system.

15. The system of claim 14, wherein the photonic power delivery system comprises a switch mode power supply configured to receive the electrical power signal and being operable to condition the electrical power signal to produce a conditioned electrical power signal.

16. The system of claim 15, wherein the photonic power delivery system comprises an amplifier configured to receive the conditioned electrical power signal and being operable to amplify an electrical data signal.

17. The system of claim 16, wherein the amplifier is configured to at least partially drive an optical modulator.

18. The system of claim 16, wherein the electrical data signal is representative of magnetic resonance data produced by a resonant coil.

19. The system of claim 14, comprising an ultrasound probe configured to receive power from the photonic power delivery system.

20. The system of claim 14, comprising additional photonic power delivery systems, each power delivery system being operable at a distinct wavelength of the beam of light, wherein the photonic power delivery systems are integrated onto a single chip or a plurality of chips.

21. An upgrade kit for a magnetic resonance imaging (MRI) system, comprising:
a chip, comprising:
a photonic data transmission system configured to interface with a plurality of radiofrequency (RF) coils and being operable to convert electrical data signals representative of magnetic resonance (MR) data generated at the RF coils into a multiplexed optical data signal representative of the MR data.

22. The kit of claim 21, wherein the photonic data transmission system comprises an optical modulator configured to receive an electrical data signal representative of a set of MR data from one of the plurality of RF coils and to modulate a subset of photons contained within a beam of light so as to encode the subset with the set of MR data to produce a set of encoded photons.

23. The kit of claim 22, wherein the photonic data transmission system comprises a waveguide interfacing with the optical modulator and configured to transmit the beam of light so as to allow the subset of photons to be modulated by the optical modulator, wherein the waveguide is configured to transmit the multiplexed optical signal away from the plurality of RF coils to as to avoid RF interference.

24. The kit of claim 23, comprising an optical resonator configured to interface with the optical fiber and configured to demultiplex the encoded set of photons out of the beam of light; and a transducer optically connected to the optical resonator and configured to convert the encoded set of photons back into the electrical data signal.

25. The kit of claim 21, comprising a photonic power delivery system having a light source being operable to produce a second beam of light; a waveguide coupled to the light source at a first end of the waveguide and configured to transmit the beam of light; and a transducer coupled to a second end of the waveguide and configured to convert the beam of light into an electrical power signal to power at least a portion of the photonic data transmission system.

26. The kit of claim 21, comprising the plurality of RF coils.
